(19) United States
(12) Patent Application Publication
(10) Pub. No.: US 2026/0129982 A1
(43) Pub. Date: May 7, 2026

(54) THREE-DIMENSIONAL STACKED IMAGE SENSORS AND METHODS FOR MAKING THREE-DIMENSIONAL STACKED IMAGE SENSORS

(71) Applicant: TELEDYNE DIGITAL IMAGING, INC., Toronto (CA)

(72) Inventor: Hyun Jung Lee, Waterloo (CA)

(21) Appl. No.: 19/377,487

(22) Filed: Nov. 3, 2025

Related U.S. Application Data
(60) Provisional application No. 63/715,090, filed on Nov. 1, 2024.

(51) Int. Cl. H10F 39/00; H10F 39/15

(52) U.S. Cl. CPC H10F 39/026; H10F 39/018; H10F 39/151; H10F 39/809; H10F 39/811

(57) ABSTRACT

Three-dimensional stacked image sensors and method for making three-dimensional stacked image sensors are provided. A method includes attaching a first CCD side of a charge-coupled device (CCD) pixel array wafer to a first carrier side of a first carrier wafer and performing a first thinning procedure on a second CCD side of the CCD pixel array wafer while the CCD pixel array wafer is attached to the first carrier wafer. The method includes forming a passivation layer on the thinned surface of the CCD pixel array wafer and temporarily bonding a second carrier wafer to the passivation layer. The method includes performing a second thinning procedure on the second carrier side of the first carrier wafer while the second carrier wafer is bonded to the passivation layer. After performing the second thinning procedure, through-silicon vias (TSVs) are formed through the first carrier wafer.

### CROSS-REFERENCE

The present application claims priority to U.S. Provisional Application No. 63/715,090, filed November 1, 2024. The entire contents of which is hereby incorporated by reference into this specification.

### BACKGROUND

Charge coupled device (CCD)-complementary metal-oxide-semiconductor (CMOS) hybrid image sensors have been used in various applications. There are challenges to manufacturing CCD-CMOS hybrid image sensors and to providing improved CCD-CMOS hybrid image sensors.

### SUMMARY

Non-limiting aspects of the present disclosure are directed to a method for manufacturing a three-dimensional stacked image sensor. The method comprises attaching a first CCD side of a charge-coupled device (CCD) pixel array wafer to a first carrier side of a first carrier wafer utilizing wafer bonding. The CCD pixel array wafer comprises the first CCD side and a second CCD side positioned opposite the first CCD side. The first carrier wafer comprises the first carrier side and a second carrier side. A plurality of CCD pixels are arranged in a form of a matrix in the first CCD side of the CCD pixel array wafer. An epitaxial layer is disposed in the second CCD side of the CCD pixel array wafer. The method comprises performing a first thinning procedure on the second CCD side of the CCD pixel array wafer while the CCD pixel array wafer is attached to the first carrier wafer, thereby at least partially exposing the epitaxial layer and forming a thinned surface on the CCD pixel array wafer. The method comprises forming a passivation layer on the thinned surface of the CCD pixel array wafer and temporarily bonding a second carrier wafer to the passivation layer. The method comprises performing a second thinning procedure on the second carrier side of the first carrier wafer while the second carrier wafer is bonded to the passivation layer. After performing the second thinning procedure, through-silicon vias (TSVs) are formed through the first carrier wafer. The method comprises electrically coupling a complementary metal-oxide-semiconductor (CMOS) readout integrated circuit (ROIC) wafer to the CCD pixel array wafer with the TSVs by direct bond interconnect (DBI) such that at least a portion of the CCD pixels are in signal communication with the ROIC wafer. The method comprises debonding the second carrier wafer, thereby forming the three-dimensional stacked image sensor.

Additional non-limiting aspects of the present disclosure is directed to a three-dimensionally stacked image sensor. The sensor comprises a first carrier wafer, a charge-coupled device (CCD) pixel array wafer, a surface passivation layer, and a complementary metal-oxide-semiconductor (CMOS) readout integrated circuit (ROIC). The CCD pixel array wafer is attached to the first carrier wafer by oxide-oxide bonding. The CCD pixel array wafer comprises an epitaxial layer, a first CCD side, and a second CCD side. A plurality of CCD pixels are arranged in a form of a matrix in the first CCD side of the CCD pixel array wafer. Metal interconnects are disposed in a second side of the CCD pixel array wafer. The metal interconnects are in signal communication with the plurality of CCD pixels and comprise a refractory metal. The surface passivation layer comprises highly doped and thermally oxidized silicon. The CMOS ROIC is coupled to the CCD pixel array by through-silicon vias (TSVs) through the first carrier wafer by direct bond interconnect (DBI) and in signal communication with the plurality of CCD pixels.

It will be understood that the inventions disclosed and described in this specification are not limited to the aspects summarized in this Summary. The reader will appreciate the foregoing details, as well as others, upon considering the following detailed description of various non-limiting and non-exhaustive aspects according to this specification.

### BRIEF DESCRIPTION OF THE DRAWINGS

The features and advantages of the examples presented herein, and the manner of attaining them, will become more apparent, and the examples will be better understood, by reference to the following description taken in conjunction with the accompanying drawings, wherein:

FIGS. 1-9 schematically illustrate aspects of a non-limiting embodiment of a method of making a three-dimensional stacked image sensor; and

FIG. 10 schematically illustrates aspects of a non-limiting embodiment a three-dimensional stacked image sensor.

The exemplifications set out herein illustrate certain non-limiting embodiments, in one form, and such exemplifications are not to be construed as limiting the scope of the appended claims and the invention in any manner.

### DETAILED DESCRIPTION

Various examples are described and illustrated herein to provide an overall understanding of the structure, function, and use of the disclosed systems, apparatus, and methods. The various examples described and illustrated herein are non-limiting and non-exhaustive. Thus, the invention is not limited by the description of the various non-limiting and non-exhaustive examples disclosed herein. Features and characteristics illustrated and/or described in connection with various examples herein may be combined with features and characteristics of other examples herein. Such modifications and variations are intended to be included within the scope of the present disclosure. The various non-limiting embodiments disclosed and described in the present disclosure can comprise, consist of, or consist essentially of the features and characteristics as variously described herein.

Any references herein to “various non-limiting embodiments”, “some non-limiting embodiments”, “certain non-limiting embodiments”, “one non-limiting embodiment”, “a non-limiting embodiment”, “an embodiment”, “one embodiment”, or like phrases mean that a particular feature, structure, act, or characteristic described in connection with the example is included in at least one embodiment. Thus, appearances of the phrases “various non-limiting embodiments”, “some non-limiting embodiments”, “certain non-limiting embodiments”, “one non-limiting embodiment”, “a non-limiting embodiment”, “an embodiment”, “one embodiment”, or like phrases in the specification do not necessarily refer to the same non-limiting embodiment. Furthermore, the particular described features, structures, or characteristics may be combined in any suitable manner in one or more non-limiting embodiments. Thus, the particular features, structures, or characteristics illustrated or described in connection with one non-limiting embodiment may be combined, in whole or in part, with the features, structures, or characteristics of one or more other non-limiting embodiments without limitation. Such modifications and variations are intended to be included within the scope of the present non-limiting embodiments.

As used herein, “at least one of” a list of elements means one of the elements or any combination of two or more of the listed elements. As an example, “at least one of A, B, and C” means A only; B only; C only; A and B; A and C; B and C; or A, B, and C.

A charge coupled device (CCD) image sensor can comprise pixels arranged in a two-dimensional array. The pixels can trap and hold photon-induced charge carriers. In a CCD image sensor, individual pixels can be separated from each other by voltage applied to surface electrodes in one direction, and channel stops (e.g., insulating barriers within the silicon substrate) in the other direction. The photoactive region of the CCD image sensor can be a p-doped epitaxial layer of silicon. There can be bias gate electrodes within the epitaxial layer and an n-doped channel below the gate electrodes. An insulating silicon dioxide layer can be grown on the epitaxial layer of the silicon substrate. Polycrystalline silicon gates can lie perpendicular to the channels and can be separated from the channels by the silicon dioxide layer.

In a complementary metal oxide semiconductor (CMOS) image sensor, each pixel can comprise a photodiode and a metal oxide semiconductor field-effect transistor (MOSFET) switch. A pixel in a CMOS image sensor can comprise a pinned photodiode, a photodetector, and transistors including a transfer gate, reset gate, selection gate, and a source-follower readout transistor, among other components. Each CMOS sensor pixel can comprise its own readout integrated circuit (ROIC) proximal to the photosensitive area.

CMOS image sensors typically can have a digital readout and include a massively parallel data path, which can lead to faster read out speeds than CCD imagers which are typically analog. CCD image sensors can have ultra-high-full well capacity (FWC) and ultra-high sensitivity, which may not be present in CMOS image sensors.

For a balance of CCD and CMOS advantages, CCD-CMOS Time Delayed Integrated TDI (CCD-CMOS TDI) image sensors have been rapidly displacing traditional CCD TDI image sensors in various applications such as, for example, industrial, machine vision, DNA sequencing, and Earth observation. The application of pattern defect inspection on semiconductor masks and wafers (M&W), which can require ultra-high FWC and ultra-high sensitivity, has not substantially realized advantages of CMOS technology. In M&W inspection, a single extreme ultra-violet (EUV) photon may generate 25 electrons and 5 electrons of the photon can be attributed to shot-noise in silicon, which can make EUV M&W inspection shot-noise limited. For example, conventional CMOS image sensors can include a lower FWC than a CCD due to the CMOS’s driving voltage being limited to 5 volts, whereas a CCD’s driving voltage can be 10 volts. CCD image sensors can comprise overlapping polycrystalline silicon gates that can be used for ultra-high-count TDI stages where a charge transfer efficiency (CTE) of 0.999999 can be desired. CMOS TDI has accomplished a CTE of 0.99999.

Traditional backside illuminated (BSI) CCD TDI image sensors for M&W applications can include off-sensor chips such as CCD drivers, analog to digital converts, timing controllers, and data transmitters, among other components, on printed circuit boards (PCBs). Including these off-sensor chips can increase the size, weight, and cost of an image sensor. Traditional BSI CCD image sensors can have reduced performance when exposed to prolonged EUV, which can be due, in part, to poor interface properties between silicon and silicon dioxide in the BSI CCD image sensors. Accordingly, the present inventor has developed a method of making a 3D stacked image sensors and 3D stacked image sensors through a CCD-CMOS integration (i.e., sensor-on-a-chip) approach, which can reduce size, weight, and/or cost of the image sensor, and/or increase resistance to degradation of the image sensor when exposed to EUV.

Referring to FIGS. 1-10, a method of manufacturing a three-dimensional (3D) image sensor is provided. Referring to FIG. 1, the method comprises providing a CCD pixel array wafer 102 and a carrier wafer 110. The CCD pixel array wafer 102 can comprise a first side 102a, a second side 102b positioned opposite the first side 102a, and metal interconnects 108. A plurality of CCD pixels 112 are arranged in a form of a matrix in the first side 102a of the CCD pixel array wafer 102, and an epitaxial layer 114 is disposed in the second side 102b of the CCD pixel array wafer 102.

The epitaxial layer 114 can be a layer of crystalline silicon formed on top of a silicon substrate of the CCD pixel array wafer 102. The epitaxial layer 114 can comprise silicon purer than silicon of the silicon substrate of the CCD pixel array wafer 102. The epitaxial layer 114 can enhance electron transfer efficiency and enhance homogeneity of the silicon substrate. In various embodiments, the epitaxial layer 114 can comprise a thickness in a range of 4 um to 30 um with a total thickness variation (TTV) of no greater than 0.5 um.

The CCD pixel array wafer 102 can be fabricated by various processes. For example, the CCD pixel array wafer 102 can be fabricated by the 3-poly, W-etchback, and Al-free CCD process.

Fabricating the CCD pixel array wafer 102 can comprise forming the silicon epitaxial layer 114 on a silicon substrate, forming a plurality of CCD pixel gates for CCD pixels 112 on the silicon epitaxial layer 114, and forming metal interconnects 108 to the CCD pixel gates using a refractory metal. The metal interconnects 108 form circuits within the CCD pixel array wafer 102 enabling electrical signals to travel from the CCD gates of the CCD pixels 112 to a desired ROIC. The CCD pixel array wafer 102, including the metal interconnects 108, can comprise a column-parallel readout structure with a single-stage source follower (SF). The CCD pixel array wafer 102 may not require aluminum metallization for routing and can be aluminum free. The silicon substrate of the CCD pixel array wafer 102 can comprise polycrystalline silicon.

The refractory metal can comprise niobium, a niobium alloy, molybdenum, a molybdenum alloy, tantalum, a tantalum alloy, tungsten, a tungsten alloy, rhenium, a rhenium alloy, titanium, a titanium alloy, vanadium, a vanadium alloy, chromium, a chromium alloy, zirconium, a zirconium alloy, ruthenium, a ruthenium alloy, rhodium, a rhodium alloy, osmium, an osmium alloy, iridium, or an iridium alloy. For example, in certain embodiments the refractory metal can comprise molybdenum, a molybdenum alloy, tungsten, or a tungsten alloy.

Referring again to FIG. 1, the method comprises attaching the first side 102a of the CCD pixel array wafer 102 to the first side 110a of the carrier wafer 110 utilizing wafer bonding. Wafer bonding can comprise various techniques, such as, for example, oxide-oxide bonding using plasma surface activation. The oxide-oxide bonding techniques can comprise cleaning of wafer surfaces, subjecting wafer surfaces to plasma, bonding, and annealing of the bonded surface.

The carrier wafer 110 can comprise the first side 110a and a second side 110b, which can be positioned opposite the first side 110a. The carrier wafer 110 can support the CCD pixel array wafer 102 during further processing. The carrier wafer 110 can comprise polycrystalline silicon.

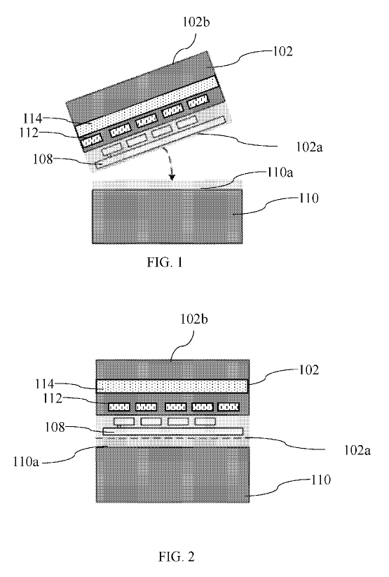

A first thinning procedure can be performed on the second side 102b of the CCD pixel array wafer 102 while the CCD pixel array wafer 102 is attached to the carrier wafer 110, as illustrated in FIG. 2, resulting in a thinned CCD pixel array wafer 102 shown in FIG. 3. Referring to FIG. 3, after the first thinning procedure, the epitaxial layer 114 can be at least partially exposed and a thinned surface 302c can be formed on the CCD pixel array wafer 102. The first thinning procedure can comprise, for example, mechanical grinding, wet acid etching, chemical-mechanical polishing (CMP), or a combination thereof. For example, the wet acid etching can comprise hydrofluoric acid, nitric acid, and acetic acid (HNA) etching. The mechanical grinding can remove silicon from the second side 102b of the CCD pixel array wafer 102.

The first thinning procedure can enable BSI, where the metal interconnects 108 can be positioned outside of a path of light entering an image sensor so that the metal interconnects 108 minimally, if at all, interfere with light traveling to the CCD pixels 112. BSI can increase the amount of light captured within an image sensor.

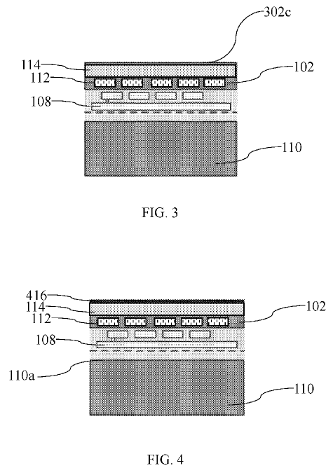

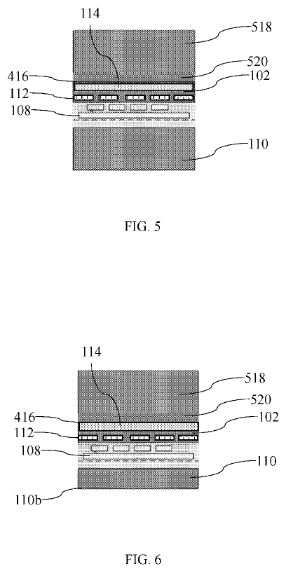

Referring to FIGS. 3-4, a passivation layer 416 can be formed on the thinned surface 302c of the CCD pixel array wafer 102. Forming the passivation layer 416 can be performed by various techniques. For example, forming the passivation layer can comprise highly doping the at least partially exposed epitaxial layer 114. Highly doping the at least partially exposed epitaxial layer 114 can comprise ion implantation, plasma-immersion ion implantation, monolayer doping (MLD), or a combination thereof. The passivation layer 416 can enhance resistance to EUV degradation.

A dopant is a substance added to a material to alter its physical properties. Adding a dopant to a silicon substrate can shift the Fermi levels within the material as dopants can introduce extra charge carriers into the silicon substrate. The dopant can be incorporated into the crystal lattice of the silicon substance. For silicon substrates, typical dopants can be acceptors from Group III or donors from Group V. For example, molecules containing boron (e.g., allylboronic acid pinacol ester) can be used for p-type doping as boron diffuses at a rate that makes junction depths easily controllable. Molecules containing phosphorus (e.g., diethyl 1-propylphosphonate) can be used for n-type doping as phosphorous diffuses fast and can be used for either bulk doping or well formation.

Following highly doping the at least partially exposed epitaxial layer 114, the dopant in the at least partially exposed epitaxial layer 114 can be activated. Activating the dopant in the at least partially exposed epitaxial layer 114 can comprise, for example, laser annealing, furnace annealing, rapid thermal annealing (RTA), spike RTA, heating the at least partially exposed epitaxial layer, or a combination thereof. For example, activating the dopant in the at least partially exposed epitaxial layer can comprise laser annealing and non-melting the epitaxial layer 114 or melting the epitaxial layer 114 at least partially. Laser annealing can utilize excimer laser annealing (ELA) or diode-pumped solid-state laser (DPSSL).

Forming the passivation layer 416 can comprise thermally oxidizing a surface of the at least partially exposed epitaxial layer 114. Thermally oxidizing the at least partially exposed epitaxial layer can comprise heating the at least partially exposed epitaxial layer 114 to a surface temperature in a range of 600 degrees Celsius to 900 degrees Celsius. Forming the passivation layer 416 prior to adding a CMOS wafer can enable high temperature thermal oxidation, which can enhance the passivation layer 416 and thereby enhance resistance to degradation from EUV.

Referring to FIG. 5, the method can comprise temporarily bonding a carrier wafer 518 to the passivation layer 416. Temporarily bonding the carrier wafer 518 to the passivation layer 416 can comprise adhesively bonding the carrier wafer 518 to the passivation layer 416 with adhesive 520.

Referring to FIG. 6, a second thinning procedure can be performed on the second side 110b of the carrier wafer 110 while the carrier wafer 518 is bonded to the passivation layer 416. The second thinning procedure can comprise, for example, mechanical grinding, wet acid etching, chemical-mechanical polishing (CMP), or a combination thereof. The mechanical grinding can remove silicon from the second side 110b of the carrier wafer 110. Removing silicon from the second side 110b of the carrier wafer 110 can enhance the formation of through-silicon vias (TSVs). For example, reducing a thickness of the carrier wafer 110 can reduce a length of a TSV formed through the carrier wafer 110. Reducing a length of the TSV can reduce the aspect ratio (height:length) of the TSV, which can enhance the manufacturability of an image sensor and/or performance of the image sensor.

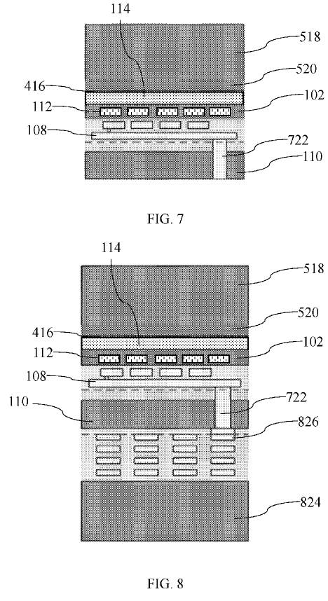

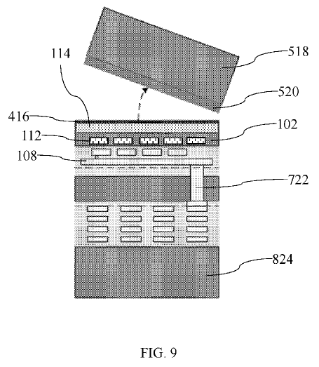

Referring to FIG. 7, after performing the second thinning procedure, TSVs 722 can be formed through the carrier wafer 110. The TSVs 722 can comprise an aspect ratio in a range of 5:1 to 20:1. It will be understood that one or more than one TSV may be formed as desired, although only one TSV is shown in FIG. 7 for clarity. TSVs can be a vertical electrical connection that passes completely through a silicon wafer that allows for stacking silicon wafers and can enable greater connectivity and/or more compact designs.

Referring to FIG. 8, a CMOS readout integrated circuit (ROIC) wafer 824 can be electronically coupled to the CCD pixel array wafer 102 by direct bond interconnect (DBI) such that at least a portion of the CCD pixels 112 are in signal communication with the CMOS ROIC wafer 824. DBI can comprises oxide-oxide wafer bonding with embedded metal interconnects. For example, DBI can comprise forming Copper-Copper bonds from metal interconnectors 826 in the CMOS ROIC wafer 824 through the TSVs 722 and to the metal interconnects 108 in the CCD pixel array wafer 102.

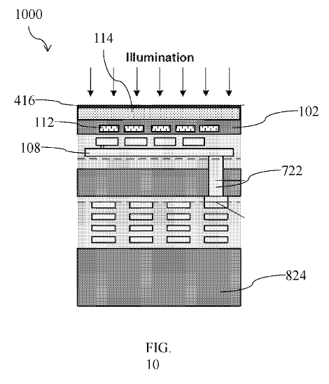

Referring to FIG. 9, the carrier wafer 518 can be debonded from the passivation layer 416, thereby forming the 3D stacked image sensor 1000 in FIG. 10. For example, the adhesive 520 may be dissolved and/or otherwise removed.

Forming the 3D stacked image sensor 1000 can enable technology advantages from CCD and CMOS. For example, the stacked image sensor 1000 can utilize enhanced FWC, enhanced CTE, and enhanced dark current sensitivity from CCD image sensors and enhanced readout speed, enhanced noise reduction, enhanced power consumption, and compact size from CMOS image sensors. The high driving and output voltages of the CCD pixel array wafer 102 being around 10 V can be interfaced to a lower voltage of the CMOS ROIC wafer 824 by shifting a voltage of the CCD substrate (e.g., negatively for n-channel CCD).

Various aspects of non-limiting embodiments of an invention according to the present disclosure include, but are not limited to, the aspects listed in the following numbered clauses.

Clause 1. A method for manufacturing a three-dimensional stacked image sensor, the method comprising: attaching a first CCD side of a charge-coupled device (CCD) pixel array wafer to a first carrier side of a first carrier wafer utilizing wafer bonding, wherein the CCD pixel array wafer comprises the first CCD side and a second CCD side positioned opposite the first CCD side, the first carrier wafer comprises the first carrier side and a second carrier side, a plurality of CCD pixels are arranged in a form of a matrix in the first CCD side of the CCD pixel array wafer, and an epitaxial layer is disposed in the second CCD side of the CCD pixel array wafer; performing a first thinning procedure on the second CCD side of the CCD pixel array wafer while the CCD pixel array wafer is attached to the first carrier wafer, thereby at least partially exposing the epitaxial layer and forming a thinned surface on the CCD pixel array wafer; forming a passivation layer on the thinned surface of the CCD pixel array wafer; temporarily bonding a second carrier wafer to the passivation layer; performing a second thinning procedure on the second carrier side of the first carrier wafer while the second carrier wafer is bonded to the passivation layer; after performing the second thinning procedure, forming through-silicon vias (TSVs) through the first carrier wafer; electrically coupling a complementary metal-oxide-semiconductor (CMOS) readout integrated circuit (ROIC) wafer to the CCD pixel array wafer with the TSVs by direct bond interconnect (DBI) such that at least a portion of the CCD pixels are in signal communication with the ROIC wafer; and debonding the second carrier wafer, thereby forming the three-dimensional stacked image sensor.

Clause 2. The method of clause 1, further comprising fabricating the CCD pixel array wafer, wherein the fabricating comprises: forming a silicon epitaxial layer on a silicon substrate; forming a plurality of CCD pixel gates on the silicon epitaxial layer; and forming metal interconnects to the CCD pixel gates using a refractory metal.

Clause 3. The method of clause 2, wherein the refractory metal comprises niobium, a niobium alloy, molybdenum, a molybdenum alloy, tantalum, a tantalum alloy, tungsten, a tungsten alloy, rhenium, a rhenium alloy, titanium, a titanium alloy, vanadium, a vanadium alloy, chromium, a chromium alloy, zirconium, a zirconium alloy, ruthenium, a ruthenium alloy, rhodium, a rhodium alloy, osmium, an osmium alloy, iridium, or an iridium alloy.

Clause 4. The method of clause 2, wherein the refractory metal comprises molybdenum, a molybdenum alloy, tungsten, or a tungsten alloy.

Clause 5. The method of any of clauses 1-4, wherein the wafer bonding comprises oxide-oxide bonding using plasma surface activation.

Clause 6. The method of any of clauses 1-5, wherein the first thinning procedure, the second thinning procedure, or both the first and second thinning procedures comprise: mechanical grinding, wet acid etching, chemical-mechanical polishing (CMP), or a combination thereof.

Clause 7. The method of clause 6, wherein wet acid etching comprises hydrofluoric acid, nitric acid, and acetic acid (HNA) etching.

Clause 8. The method of any of clauses 1-7, wherein the first thinning procedure comprise removing silicon from the first CCD side of the CCD pixel array wafer by mechanical grinding, wet acid etching, chemical-mechanical polishing (CMP), or a combination thereof, thereby exposing a surface of the epitaxial layer.

Clause 9. The method of any of clauses 1-8, wherein a thickness of the epitaxial layer is in a range of 4 um to 30 um with a total thickness variation of no greater than 0.5 um.

Clause 10. The method of any of clauses 1-9, wherein forming the passivation layer comprises: highly doping the at least partially exposed epitaxial layer; activating dopant in the at least partially exposed epitaxial layer; and thermally oxidizing the at least partially exposed epitaxial layer.

Clause 11. The method of clause 10, wherein highly doping the at least partially exposed epitaxial layer comprises ion implantation, plasma-immersion ion implantation, monolayer doping (MLD), or a combination thereof.

Clause 12. The method of any of clauses 10-11, wherein activating the dopant in the at least partially exposed epitaxial layer comprises laser annealing, furnace annealing, rapid thermal annealing (RTA), spike RTA, heating the at least partially exposed epitaxial layer to a temperature, or a combination thereof.

Clause 13. The method of any of clauses 10-12, wherein activating the dopant in the at least partially exposed epitaxial layer comprises laser annealing and non-melting the epitaxial layer or melting the epitaxial layer at least partially.

Clause 14. The method of any of clauses 10-13, wherein activating the dopant in the at least partially exposed epitaxial layer comprises laser annealing using excimer laser annealing (ELA) or diode-pumped solid-state laser (DPSSL) annealing.

Clause 15. The method of any of clauses 10-15, wherein thermally oxidizing the at least partially exposed epitaxial layer comprises heating to a surface temperature in a range of 600 degrees Celsius to 900 degrees Celsius.

Clause 16. The method of any of clauses 1-15, wherein temporarily bonding the second carrier wafer to the passivation layer comprises adhesively bonding the second carrier wafer to the passivation layer.

Clause 17. The method of any of clauses 1-16, wherein the TSVs have an aspect ratio in a range of 5:1 to 20:1.

Clause 18. The method of any of clauses 1-17, wherein the DBI comprises oxide-oxide wafer bonding with embedded metal interconnects.

Clause 19. A three-dimensionally stacked image sensor comprising: a first carrier wafer; a charge-coupled device (CCD) pixel array wafer attached to the first carrier wafer by oxide-oxide bonding, wherein the CCD pixel array wafer comprises an epitaxial layer, a first CCD side, and a second CCD side, a plurality of charge-coupled device (CCD) pixels are arranged in a form of a matrix in the first CCD side of the CCD pixel array wafer, and metal interconnects are disposed in a second side of the CCD pixel array wafer, wherein the metal interconnects are in signal communication with the plurality of CCD pixels and comprise a refractory metal; a surface passivation layer comprising highly doped and thermally oxidized silicon; and a complementary metal-oxide-semiconductor (CMOS) readout integrated circuit (ROIC) coupled to the CCD pixel array by through-silicon vias (TSVs) through the first carrier wafer by direct bond interconnect (DBI) and in signal communication with the plurality of CCD pixels.

In the present disclosure, unless otherwise indicated, all numerical parameters are to be understood as being prefaced and modified in all instances by the term “about,” in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described herein should at least be construed in light of the number of reported significant digits and by applying ordinary rounding techniques.

Also, any numerical range recited herein includes all sub-ranges subsumed within the recited range. For example, a range of “1 to 10” includes all sub-ranges between (and including) the recited minimum value of 1 and the recited maximum value of 10, that is, having a minimum value equal to or greater than 1 and a maximum value equal to or less than 10. Any maximum numerical limitation recited in this specification is intended to include all lower numerical limitations subsumed therein, and any minimum numerical limitation recited in the present disclosure is intended to include all higher numerical limitations subsumed therein. Accordingly, Applicant reserves the right to amend the present disclosure, including the claims, to expressly recite any sub-range subsumed within the ranges expressly recited. All such ranges are inherently described in the present disclosure.

The grammatical articles “a,” “an,” and “the,” as used herein, are intended to include “at least one” or “one or more,” unless otherwise indicated, even if “at least one” or “one or more” is expressly used in certain instances. Thus, the foregoing grammatical articles are used herein to refer to one or more than one (i.e., to “at least one”) of the particular identified elements. Further, the use of a singular noun includes the plural, and the use of a plural noun includes the singular, unless the context of the usage requires otherwise.

The foregoing detailed description has set forth various forms of the devices and/or processes via the use of schematic illustrations and examples. Insofar as such schematics and examples include functions and/or operations, it will be understood by those skilled in the art that each function and/or operation in such schematics and examples can be implemented, individually and/or collectively, by a wide range of hardware, software, firmware, or virtually any combination thereof. Those skilled in the art will recognize that some examples of the forms

disclosed herein, in whole or in part, may be equivalently implemented in integrated circuits, as a computer program running on a computer (e.g., as a programs running on a computer system), as a program running on a processor (e.g., as a program running on a microprocessor), as firmware, or as virtually any combination thereof, and that designing the circuitry and/or writing the code for the software and or firmware would be well within the skill of one skilled in the art in light of this disclosure. In addition, those skilled in the art will appreciate that the mechanisms of the subject matter described herein are capable of being distributed as a program product in a variety of forms, and an illustrative form of the subject matter described herein applies regardless of the particular type of signal bearing medium used to actually carry out the distribution.

One skilled in the art will recognize that the herein described apparatus, systems, structures, methods, operations/actions, and objects, and the discussion accompanying them, are used as examples for the sake of conceptual clarity and that various configuration modifications are contemplated. Consequently, as used herein, the specific examples/embodiments set forth and the accompanying discussion are intended to be representative of their more general classes. In general, use of any specific exemplar is intended to be representative of its class and the non-inclusion of specific components, devices, apparatus, operations/actions, and objects should not be taken as limiting. While the present disclosure provides descriptions of various specific aspects for the purpose of illustrating various aspects of the present disclosure and/or its potential applications, it is understood that variations and modifications will occur to those skilled in the art. Accordingly, the invention or inventions described herein should be understood to be at least as broad as they are claimed and not as more narrowly defined by particular illustrative aspects provided herein.

What is claimed is:

1. A method for manufacturing a three-dimensional stacked image sensor, the method comprising:
attaching a first CCD side of a charge-coupled device (CCD) pixel array wafer to a first carrier side of a first carrier wafer utilizing wafer bonding, wherein the CCD pixel array wafer comprises the first CCD side and a second CCD side positioned opposite the first CCD side, the first carrier wafer comprises the first carrier side and a second carrier side, a plurality of CCD pixels are arranged in a form of a matrix in the first CCD side of the CCD pixel array wafer, and an epitaxial layer is disposed in the second CCD side of the CCD pixel array wafer;
performing a first thinning procedure on the second CCD side of the CCD pixel array wafer while the CCD pixel array wafer is attached to the first carrier wafer, thereby at least partially exposing the epitaxial layer and forming a thinned surface on the CCD pixel array wafer;
forming a passivation layer on the thinned surface of the CCD pixel array wafer;
temporarily bonding a second carrier wafer to the passivation layer;
performing a second thinning procedure on the second carrier side of the first carrier wafer while the second carrier wafer is bonded to the passivation layer;
after performing the second thinning procedure, forming through-silicon vias (TSVs) through the first carrier wafer;
electrically coupling a complementary metal-oxide-semiconductor (CMOS) readout integrated circuit (ROIC) wafer to the CCD pixel array wafer with the TSVs by direct bond interconnect (DBI) such that at least a portion of the CCD pixels are in signal communication with the ROIC wafer; and
debonding the second carrier wafer, thereby forming the three-dimensional stacked image sensor.

2. The method of claim 1, further comprising
fabricating the CCD pixel array wafer, wherein the fabricating comprises:
forming a silicon epitaxial layer on a silicon substrate;
forming a plurality of CCD pixel gates on the silicon epitaxial layer; and
forming metal interconnects to the CCD pixel gates using a refractory metal.

3. The method of claim 2, wherein the refractory metal comprises niobium, a niobium alloy, molybdenum, a molybdenum alloy, tantalum, a tantalum alloy, tungsten, a tungsten alloy, rhenium, a rhenium alloy, titanium, a titanium alloy, vanadium, a vanadium alloy, chromium, a chromium alloy, zirconium, a zirconium alloy, ruthenium, a ruthenium alloy, rhodium, a rhodium alloy, osmium, an osmium alloy, iridium, or an iridium alloy.

4. The method of claim 2, wherein the refractory metal comprises molybdenum, a molybdenum alloy, tungsten, or a tungsten alloy.

5. The method of claim 1, wherein the wafer bonding comprises oxide-oxide bonding using plasma surface activation.

6. The method of claim 1, wherein the first thinning procedure, the second thinning procedure, or both the first and second thinning procedures comprise:
mechanical grinding, wet acid etching, chemical-mechanical polishing (CMP), or a combination thereof.

7. The method of claim 6, wherein wet acid etching comprises hydrofluoric acid, nitric acid, and acetic acid (HNA) etching.

8. The method of claim 1, wherein the first thinning procedure comprise removing silicon from the first CCD side of the CCD pixel array wafer by mechanical grinding, wet acid etching, chemical-mechanical polishing (CMP), or a combination thereof, thereby exposing a surface of the epitaxial layer.

9. The method of claim 1, wherein a thickness of the epitaxial layer is in a range of 4 um to 30 um with a total thickness variation of no greater than 0.5 um.

10. The method of claim 1, wherein forming the passivation layer comprises:
highly doping the at least partially exposed epitaxial layer;
activating dopant in the at least partially exposed epitaxial layer; and
thermally oxidizing the at least partially exposed epitaxial layer.

11. The method of claim 10, wherein highly doping the at least partially exposed epitaxial layer comprises ion implantation, plasma-immersion ion implantation, monolayer doping (MLD), or a combination thereof.

12. The method of claim 10, wherein activating the dopant in the at least partially exposed epitaxial layer comprises laser annealing, furnace annealing, rapid thermal annealing (RTA), spike RTA, heating the at least partially exposed epitaxial layer to a temperature, or a combination thereof.

13. The method of claim 10, wherein activating the dopant in the at least partially exposed epitaxial layer comprises laser annealing and non-melting the epitaxial layer or melting the epitaxial layer at least partially.

14. The method of claim 10, wherein activating the dopant in the at least partially exposed epitaxial layer comprises laser annealing using excimer laser annealing (ELA) or diode-pumped solid-state laser (DPSSL) annealing.

15. The method of claim 10, wherein thermally oxidizing the at least partially exposed epitaxial layer comprises heating to a surface temperature in a range of 600 degrees Celsius to 900 degrees Celsius.

16. The method of claim 1, wherein temporarily bonding the second carrier wafer to the passivation layer comprises adhesively bonding the second carrier wafer to the passivation layer.

17. The method of claim 1, wherein the TSVs have an aspect ratio in a range of 5:1 to 20:1.

18. The method of claim 1, wherein the DBI comprises oxide-oxide wafer bonding with embedded metal interconnects.

19. A three-dimensionally stacked image sensor comprising:
a first carrier wafer;
a charge-coupled device (CCD) pixel array wafer attached to the first carrier wafer by oxide-oxide bonding, wherein the CCD pixel array wafer comprises an epitaxial layer, a first CCD side, and a second CCD side, a plurality of charge-coupled device (CCD) pixels are arranged in a form of a matrix in the first CCD side of the CCD pixel array wafer, and metal interconnects are disposed in a second side of the CCD pixel array wafer, wherein the metal interconnects are in signal communication with the plurality of CCD pixels and comprise a refractory metal;
a surface passivation layer comprising highly doped and thermally oxidized silicon; and
a complementary metal-oxide-semiconductor (CMOS) readout integrated circuit (ROIC) coupled to the CCD pixel array by through-silicon vias (TSVs) through the first carrier wafer by direct bond interconnect (DBI) and in signal communication with the plurality of CCD pixels.
